(19) United States
(12) Patent Application Publication
(10) Pub. No.: US 2008/0294963 A1
(43) Pub. Date: Nov. 27, 2008

(54) METHOD AND APPARATUS FOR DESIGNING LOW DENSITY PARITY CHECK CODE WITH MULTIPLE CODE RATES, AND INFORMATION STORAGE MEDIUM THEREOF

(75) Inventor: SUNG-HEE HWANG, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/958,498

(22) Filed: Dec. 18, 2007

(30) Foreign Application Priority Data
May 22, 2007 (KR) 2007-0049957

(51) Int. Cl. H03M 13/05; G06F 11/10

(52) U.S. Cl. 714/755; 714/752; 714/E11.032

(57) ABSTRACT

A method and apparatus for generating a low density parity check (LDPC) code having a variable code rate, the method of generating the LDPC code having a variable code rate including: generating a first parity check matrix by combining a parity matrix or a parity check matrix and a first information word matrix; and generating a second parity check matrix by combining the first parity check matrix and a second information word matrix. According to the method and apparatus, error correction performance is enhanced.

### CROSS-REFERENCE TO RELATED APPLICATION

This application claims the benefit of Korean Application No. 2007-49957, filed on May 22, 2007 in the Korean Intellectual Property Office, the disclosure of which is incorporated herein by reference.

### BACKGROUND OF THE INVENTION

1. Field of the Invention

Aspects of the present invention relate to a method and apparatus to generate a low density parity check (LDPC) code with a variable code rate, and an information storage medium thereof.

2. Description of the Related Art

With the rapid development of mobile communication systems, a technology allowing a large amount of data (comparable to a transmission capacity of a wired network) to be transmitted through a wireless network is in demand. Shifting away from voice-focused services, high speed large capacity communication systems that are capable of processing and transmitting a variety of information (such as images and wireless data), are thus also in demand. Accordingly, enhancing transmission efficiency of the system by using an appropriate channel coding method has become an essential element in enhancing the performance of the system. However, in a mobile communication system, errors unavoidably occur due to noise, interference and fading according to the environment of channels and the characteristic of the mobile communication system. As a result, loss of data is caused by errors.

In order to reduce the loss of the data due to the occurrence of errors, a variety of error control methods are used in relation to the characteristics of a channel. Thus, reliability of the mobile communication system can be enhanced. An error control method that is most widely used from among the convention error control methods utilizes an error correction code.

Structures of a transmitter and a receiver of a conventional communication system will now be explained with reference to FIG. 1. FIG. 1 is a schematic diagram illustrating a structure of a transmitter 100 and a receiver 150 of a conventional communication system. Referring to FIG. 1, a transmitter 100 includes an encoder 111, a modulator 113, and a radio frequency (RF) processor 115, and a receiver 150 includes an RF processor 151, a demodulator 153, and a decoder 155.

Data u to be transmitted by the transmitter 100 is first transferred to the encoder 111. The encoder 111 encodes the data u according to a predetermined encoding method, thereby generating an encoded data signal c, and outputs the encoded data signal c to the modulator 113. The modulator 113 modulates the encoded data signal c according to a predetermined modulation method, thereby generating a modulated data signal s, and outputs the modulated data signal s to the RF processor 115. The RF processor 115 receives the data signal s output by the modulator 113, RF-processes the data signal s, and transmits the data signal through an antenna.

The data signal transmitted by the transmitter 100 is received through an antenna of the receiver 150, and transferred to the RF processor 151. The RF processor 151 RF-processes the received data signal and outputs the RF-processed signal s to the demodulator 153. The demodulator 153 receives the data signal s output by the RF processor 151, demodulates the data signal s according to a demodulation method corresponding to the modulation method that is applied by the modulator 113 of the transmitter 100, and outputs the demodulated data signal x to the decoder 155. The decoder 155 receives the data signal x output by the demodulator 153, decodes the data signal x according to a decoding method corresponding to the encoding method that is applied by the encoder 111 of the transmitter 100, and outputs the decoded signal 0 as data that is finally restored.

In order to more efficiently restore the data u transmitted by the transmitter 100, an encoder and decoder with higher performances have been increasingly demanded. In particular, due to the characteristics of a mobile communication system, a wireless channel environment should be considered. Accordingly, an error that can occur in the wireless channel environment should be considered.

Examples of the error correction code include a turbo code and a low density parity check (LDPC) code. The turbo code has a better performance gain for high speed data transmission than that of a convolution code. The turbo code has an advantage in that an error caused by noise generated in a transmission channel can be effectively corrected, thereby increasing the reliability of the data transmission. In contrast, the LDPC code can be decoded by using an iterative decoding algorithm based on a sum-product algorithm on a factor graph. Since a decoder of the LDPC code uses the iterative decoding algorithm based on the sum-product algorithm, the decoder has a lower complexity than that of a decoder of the turbo code. In addition, it is easier to implement the LDPC decoder as a parallel processing decoder.

Meanwhile, a channel coding theorem by Shannon states that only a data rate that does not exceed the capacity of a channel enables reliable communication. However, the Shannon channel coding theorem has never suggested any specific channel coding and decoding method supporting a data rate up to the maximum capacity of a channel. Generally, a random code with a big block size has a performance close to the limit of a channel capacity according to the Shannon's channel coding theorem. However, when a maximum a posteriori (MAP) or maximum likelihood (ML) decoding method is used, the amount of computation causes a huge load making it is impossible to actually implement the code.

The turbo code was introduced by Berrou, Glavieux, and Thitimajshima in 1933, and has a good performance close to the limit of a channel capacity according to the Shannon channel coding theorem. Due to the suggestion of the turbo code, research on iterative decoding and graph expression of codes has begun to be actively carried out. Also, in a similar time period, Gallager suggest the LDPC code. In addition, cycles exist in the factor graphs of the turbo code and the LDPC code, and iterative decoding on the factor graph of the LDPC code is suboptimal. It has also been experimentally proven that the LDPC code has a good performance through iterative decoding. The LDPC code shows an excellent performance that has a difference of only about 0.04 dB with the limit of the channel capacity according to the Shannon channel coding theorem, at a bit error rate (BER) of 10⁻⁵ by using a block size 10⁷. Also, although an LDPC code that is defined in a Galois field (GF) in which q>2 (i.e., GF(q)) increases the complexity of the decoding process, the LDPC code has a much better performance than that of a binary code. However, a theoretical explanation of successful decoding of an iterative decoding algorithm of the LDPC code defined in the GF(q) has not been satisfactorily given.

In the LDPC code, most elements have zero values. More specifically, the LDPC code is defined by a parity check matrix in which very few elements (other than the elements having zero values) have non-zero values (for example, 1). Hereinafter, for convenience of explanation, it is assumed that the non-zero value is 1.

For example, an (N,j,k) LDPC code is a linear block code in which the length of a block is N. The (N,j,k) LDPC code is defined by a parity check matrix having a sparse structure in which j elements having a value of 1 exist in each column, k elements having a value of 1 exist in each row, and the remaining elements each have values of 0's.

An LDPC code in which the weight of each column in the parity check matrix is constant and is given as j and the weight of each row in the parity check matrix is constant and is given as k, as described above, is known as a regular LDPC code. Here, the weight indicates the number of elements having non-zero values from among elements forming the parity check matrix. In contrast, an LDPC code in which the weight of each column and the weight of each row are not constant is known as an irregular LDPC code. In general, the performance of the irregular LDPC code is better than the performance of the regular LDPC code. However, in the case of the irregular LDPC code, the superior performance can be guaranteed only when the weight of each column and the weight of each row in the parity check matrix are appropriately adjusted.

The parity check matrix of an (8,2,4) LDPC code as an example of the (N,j,k) LDPC code will now be explained with reference to FIG. 2. FIG. 2 is a diagram illustrating a parity check matrix of an ordinary (8,2,4) (LDPC) code according to conventional technology. Referring to FIG. 2, the regular parity check matrix of the (8,2,4) LDPC code is formed by 8 columns and 4 rows, where the weight of each column is 2 and the weight of each row is 4. Thus, since the weight of each column and the weight of each row in the parity check matrix are regular, the (8,2,4) LDPC code illustrated in FIG. 2 is a regular LDPC code.

A factor graph of the (8,2,4) LDPC code described above with reference to FIG. 2 will now be explained with reference to FIG. 3. FIG. 3 is a diagram illustrating a factor graph of the (8,2,4) LDPC code illustrated in FIG. 2. Referring to FIG. 3, the factor graph of the (8,2,4) LDPC code is formed by eight variable nodes (i.e., x₁ 300 through x₈ 314), and four check nodes 316, 318, 320, and 322. If an element having a value of 1 (i.e., a non-zero value) exists at the intersection of an i-th row and a j-th column in the parity check matrix of the (8,2,4) LDPC code, a branch is generated between a variable node xᵢ and a j-th check node.

As described above, since the parity check matrix of the LDPC code has a small weight, decoding of the code is enabled through iterative decoding even in a block code having a relatively longer length. Moreover, if the block length of a block code is continuously increased, the performance close to the Shannon limit of the channel capacity (as in the turbo code) is obtained. Furthermore, MacKay and Neal have already proven that the iterative decoding process of the LDPC code using a flow transfer method has a performance very close to that of the iterative decoding process of the turbo code.

Meanwhile, in order to generate an LDPC code having a better performance, several conditions as described below should be satisfied. First, a cycle on the factor graph of an LDPC code should be considered. The cycle is a loop that is formed by edges connecting variable nodes and check nodes in the factor graph of the LDPC code, and the length of the cycle is defined by the number of edges forming the loop. A longer length of the cycle indicates that the number of edges connecting variable nodes and check nodes forming the loop in the factor graph of the LDPC code is large. Conversely, a short length of the cycle indicates that the number of edges connecting variable nodes and check nodes forming the factor loop in the factor graph of the LDPC code is small. The longer the cycle on the factor graph of the LDPC code, the better the performance of the LDPC code. This is because an error floor (occurring when the factor graph of the LDPC code has many cycles with short lengths) does not occur when the cycle of the factor graph of the LDPC code is generated to be long.

Second, efficient encoding of an LDPC code should be considered. The LDPC code has a higher encoding complexity than that of a convolution code or turbo code due to the characteristics of the LDPC code. Therefore, it is difficult to encode the LDPG code in real-time. In order to reduce the encoding complexity of the LDPC code, a repeat accumulate (RA) code has been suggested. However, the reduction of the encoding complexity of the LDPC code by the RA code is also limited. Accordingly, efficient encoding of the LDPC code should be considered.

Third, degree distribution on the factor graph of an LDPC code should be considered. Generally, the performance of an irregular LDPC code is better than that of a regular LDPC code because the irregular LDPC code has a variety of degrees in the factor graph. Here, the degree is the number of edges connected to each node on the factor graph of the LDPC code (i.e., variable nodes and check nodes). Also, the degree distribution on the factor graph of the LDPC code indicates the portion of nodes having a predetermined degree. An improved performance of an LDPC code having a predetermined degree distribution has already been proven by Richardson and others.

The parity check matrix of a block LDPC code will now be explained with reference to FIG. 4. FIG. 4 is a diagram illustrating a parity check matrix of a block LDPC code according to conventional technology. The block LDPC code is a new LDPC code that considers both storage and performance improvement of an efficient parity check matrix as well as efficient encoding. Accordingly, the block LDPC code is an LDPC code with an extended concept obtained by generalizing the structure of a regular LDPC code.

Referring to FIG. 4, the parity check matrix of the block LDPC code has a shape in which an entire parity check matrix is divided into a plurality of partial blocks, and a permutation matrix is matched with each partial block. “P” illustrated in FIG. 4 indicates a permutation matrix with a size of Ns*Ns. The superscript a_{pq} of the permutation matrix P satisfies 0<a_{pq}<Ns or a_{pq}=∞. The subscript “p” indicates that the permutation matrix is located at a p-th row in a plurality of partial blocks of the parity check matrix, and “Q” indicates that the permutation matrix is located at a Q-th column in the plurality of partial blocks. That is, p^{a}^{_{pq}} indicates a permutation matrix existing in a partial block at the intersection of the p-th row and the Q-th column of the parity check matrix formed with the plurality of partial blocks. That is, p and Q indicate the number of rows and the number of columns, respectively, of the partial blocks corresponding to the information part in the parity check matrix.

According to the conventional matrix generation method, different matrices are generated with respect to different encoding rates. However, in this case, describing a matrix appropriate for each encoding rate in a specification and reflecting the matrix in a recording and reproducing apparatus results in a more complicated specification and more complicated structure of the recording and reproducing apparatus.

### SUMMARY OF THE INVENTION

Aspects of the present invention provide a method and apparatus for generating an LDPC code with a variable code rate capable of improving the performance of error correction, and an information storage medium thereof.

According to an aspect of the present invention, there is provided a method of generating a low density parity check (LDPC) code having a variable code rate, the method including: generating a first parity check matrix by combining a parity matrix or a parity check matrix and a first information word matrix; and generating a second parity check matrix by combining the first parity check matrix and a second information word matrix.

The generating of the first parity check matrix may include generating the first parity check matrix so that a minimum distance and/or a girth of the first parity check matrix is a maximum, and the generating of the second parity check matrix includes generating the second parity check matrix so that a minimum distance and/or a girth of the second parity check matrix is a maximum.

The minimum distance and/or the girth of the generated first parity check matrix may be greater than or equal to the minimum distance and/or the girth of the generated second parity check matrix.

The generating of the parity check matrix may further include generated a third parity check matrix by combining the second parity check matrix and a third information word matrix.

A code rate of the first parity check matrix may be lower than a code rate of the second parity check matrix.

The first information word matrix and the second information word matrix may be formed by columns each having a weight less than or equal to a predetermined weight.

The method may further include taking the second parity check matrix as a mother matrix and replacing each factor of the mother matrix with a sub matrix.

The replacing of each factor with the sub matrix may include: generating the sub matrices so that the minimum distance and/or the girth of the first parity check matrix in which each factor is replaced by the sub matrix is a maximum; and generating the sub matrices so that the minimum distance and/or the girth of the second parity check matrix in which each factor is replaced by the sub matrix is a maximum.

The minimum distance of the first parity check matrix in which each factor is replaced by the sub matrix may be greater than or equal to the minimum distance of the second parity check matrix in which each factor is replaced by the sub matrix.

According to another aspect of the present invention, there is provided an information storage medium storing an LDPC code word having a variable code rate, wherein the code word includes a first parity check matrix generated by combining a parity matrix or a parity chec matrix and a first information word matrix, and a second parity check matrix generated by combining the first parity check matrix and a second information word matrix.

According to still another aspect of the present invention, there is provided an apparatus for generating an LDPC code word having a variable code rate, the apparatus including: an information word generation unit to generate an N-th information word matrix, where N is an integer greater than or equal to 1; and a parity check matrix generation unit to generate an N-th parity check matrix by combining the generated N-th information word matrix and a parity matrix or an (N-1)-th parity check matrix.

The parity check matrix generation unit may generate a first parity check matrix by combining the parity matrix and a first information word matrix, and generate a second parity check matrix by combining the first parity check matrix and a second information word matrix.

The parity check matrix generation unit may generate the first parity check matrix so that a minimum distance and/or a girth of the first parity check matrix is a maximum, and may generate the second parity check matrix so that a minimum distance and/or a girth of the second parity check matrix is a maximum.

The minimum distance and/or the girth of the generated first parity check matrix may be greater than or equal to the minimum distance and/or the girth of the generated second parity check matrix.

The apparatus may further include a mother matrix extension unit to replace each factor of the second parity check matrix with a sub matrix.

The mother matrix extension unit may generate the sub matrices so that the minimum distance and/or the girth of the first parity check matrix in which each factor is replaced by the sub matrix is a maximum, and generate the sub matrices so that the minimum distance and/or the girth of the second parity check matrix in which each factor is replaced by the sub matrix is a maximum.

The minimum distance of the first parity check matrix in which each factor is replaced by the sub matrix may be greater than or equal to the minimum distance of the second parity check matrix in which each factor is replaced by the sub matrix.

According to yet another aspect of the present invention, there is provided a method of generating an LDPC code word having a variable code rate, the method including: generating an N-th information word matrix, where N is an integer greater than or equal to 1; and generating an N-th parity check matrix by combining the generated N-th information word matrix and a parity matrix or an (N-1)-th parity check matrix.

According to another aspect of the present invention, there is provided a method of extending an LDPC code having a variable code rate and including a parity check matrix, the method including: replacing each factor of the parity check matrix with a sub matrix, wherein a minimum distance and/or a girth of the parity check matrix in which each factor is replaced is a maximum.

According to still another aspect of the present invention, there is provided an apparatus for extending an LDPC code having a variable code rate and including a parity check matrix, the apparatus including: a matrix extension unit to replace each factor of the parity check matrix with a sub matrix, wherein a minimum distance and/or a girth of the parity check matrix in which each factor is replaced is a maximum.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram illustrating a structure of a transmitter and a receiver of a conventional communication system;

FIG. 2 is a diagram illustrating a conventional parity check matrix of an (8,2,4) low density parity check (LDPC) code;

FIG. 3 is a diagram illustrating a factor graph of the (8,2,4) LDPC code illustrated in FIG. 2;

FIG. 4 is a diagram illustrating a conventional parity check matrix of a block LDPC code according;

FIG. 5 is a diagram illustrating a parity matrix and an information word matrix according to an embodiment of the present invention;

FIG. 6 is a flowchart illustrating a method of generating an LDPC code according to an embodiment of the present invention;

FIG. 7 is a flowchart illustrating a method of extending an LDPC code according to an embodiment of the present invention;

FIG. 8 is a block diagram illustrating an apparatus for generating an LDPC code word according to an embodiment of the present invention;

FIG. 9 is a diagram illustrating a parity matrix and an information word matrix according to an embodiment of the present invention;

FIG. 10 is a diagram illustrating an LDPC code that is generated in relation to the parity matrix and information word matrix illustrated in FIG. 9 according to an embodiment of the present invention;

FIG. 11 is a diagram illustrating an LDPC code obtained by replacing a mother matrix illustrated in FIG. 10 with a sub matrix according to an embodiment of the present invention; and

FIGS. 12A through 12C are graphs illustrating error rates of conventional LDPC codes and the LDPC codes according to an embodiment of the present invention.

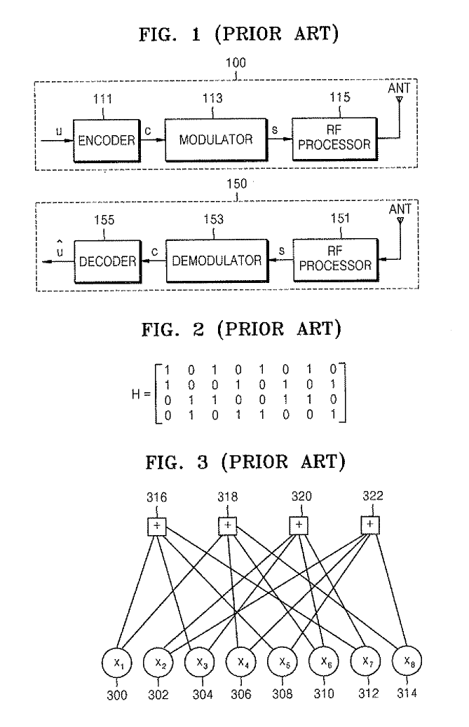

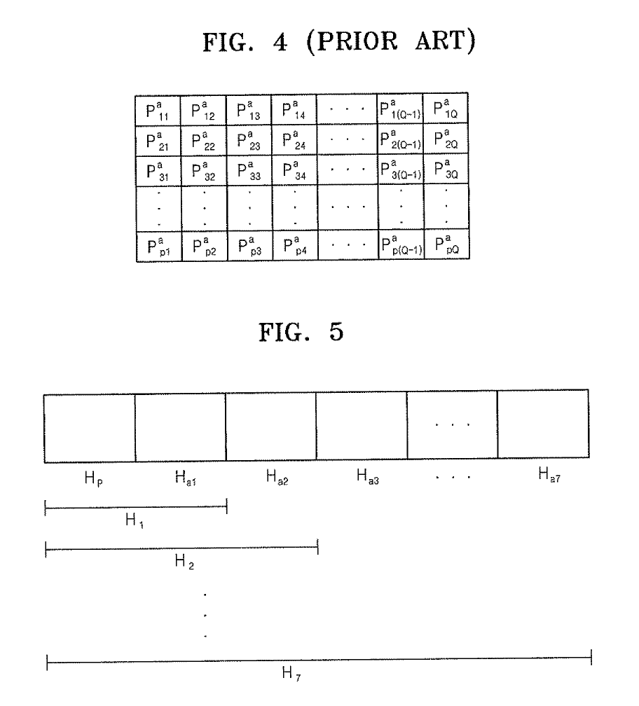

### DETAILED DESCRIPTION OF THE INVENTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

FIG. 5 is a diagram illustrating a parity matrix and an information word matrix according to an embodiment of the present invention. Referring to FIG. 5, Hp indicates a parity matrix and Ha1 through Han (where n in the current embodiment is equal to 7) indicate information word matrices. It is understood that n may have another value other than 7. A code word is formed by an information word and a parity. More specifically, the parity check matrix of a low density parity check (LDPC) code supporting n code rates includes a k*1 parity matrix Hp for the parity part, and generates an H1 matrix for the LDPC supporting a lowest code rate (R1) by adding Ha1 to Hp. The generated matrix can be expressed as H1=[Hp|Ha1].

After generating the H1 matrix, an H2 matrix of the LDPC supporting a second lowest code rate (R2) is generated by adding Ha2 to the generated H1 matrix. The generated matrix can be expressed as H2 [H1|Ha2]=[Hp|Ha1|Ha2]. In order to generate an H3 matrix of LDPC supporting a third lowest code rate (R3), H2 is added to Ha3. The generated matrix is expressed as H3=[H2|Ha3]=[H1|Ha1|Ha2]=[Hp|Ha1|Ha2|Ha3]. In the same manner, an Hn matrix for a n-th lowest code rate (Rn) can be expressed as Hn=[Hp|Ha1|Ha2] . . . Han.

Each information word matrix Hai (where i=1, 2, through n) may be formed by columns having weights less than or equal to a predetermined reference value, and columns having weights greater than the predetermined reference value. A matrix RHai formed by columns having weights less than or equal to the predetermined reference value among the columns of the information word matrix Hai can be expressed as RHai=[Hp|RHa1|RHa2| . . . |RHai] (i=1, 2, through n).

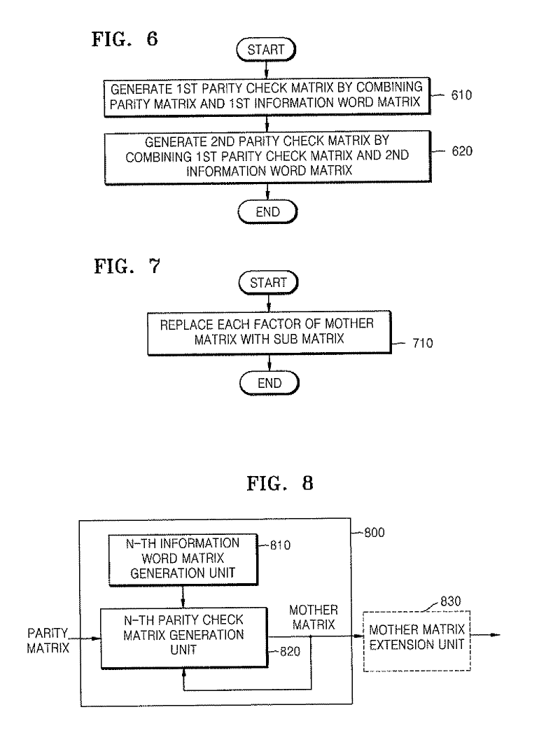

FIG. 6 is a flowchart illustrating a method of generating an LDPC code according to an embodiment of the present invention. Referring to FIG. 6, a first parity check matrix is generated by combining a parity matrix and a first information word matrix in operation 610. That is, referring to FIG. 5, the H1 matrix is generated by combining the Hp matrix and the Ha1 matrix. In this case, the code rate of the H1 matrix is a minimum, and the weight of each column has a value less than or equal to a predetermined reference value.

Thus, when the first parity check matrix is generated, the first parity check matrix may be generated so that the minimum distance or girth of the first parity check matrix is a maximum. The minimum distance indicates a minimum number of columns in which a linear combination of column vectors is linearly dependent. If the minimum distance of the first parity check matrix has a maximum value, the performance of the first parity check matrix improves accordingly. The girth indicates a minimum cycle of the matrix, and refers to a minimum number of movements between edges when the cycle begins from one edge (a location where the value of an entry is 1) of the matrix and returns to the beginning position through neighboring edges in the horizontal and vertical directions. The greater the girth, the better the performance of the matrix.

Next, a second parity check matrix is generated by combining the first parity check matrix and a second information word matrix in operation 620. Referring to FIG. 5, an H2 matrix (the second parity check matrix) is generated by combining the H1 matrix and the Ha2 matrix. In this case, the code rate of the H2 matrix is greater than the code rate of the H1 matrix, and the weight of each column has a value less than or equal to a predetermined reference value. Thus, when the second parity check matrix is generated, the second parity check matrix may be generated so that the minimum distance or girth of the second parity check matrix is a maximum. Moreover, the minimum distance of the second parity check matrix may be less than or equal to the minimum distance of the first parity check matrix. Similarly, the girth of the second parity check matrix may be less than or equal to the girth of the first parity check matrix.

The girth can be made to be bigger with a lower code rate, and smaller with a higher code rate. Generally, although not necessarily, when an LDPC code is generated, the LDPC is designed to have a girth of 6, 8, or 10 while avoiding a girth of 4. Aspects of the present invention may design the girth of 8 when the girth of RH2 is 6, if the design of the girth of 8 is possible. This is because if when RH2 is to be designed, RH1 is not considered first, and a girth of 6 is set to 6 for only RH2, it is probable that the girth of RH1 becomes 6. Then, the performance of the LDPC code is lowered.

Though FIG. 6 illustrates only the first parity check matrix and the second parity check matrix, it is understood that aspects of the present invention can be sequentially expanded to design n parity check matrices. As n becomes bigger, the code rate increases and the minimum distance becomes equal to or less than the previous parity check matrix.

FIG. 7 is a flowchart illustrating a method of extending an LDPC code according to an embodiment of the present invention. Referring to FIG. 7, each factor of a mother matrix is replaced by a sub matrix in operation 710. The mother matrix is an N-th parity check matrix (i.e., the final result obtained by the method explained above with reference to FIG. 6). That is, by replacing each factor of the N-th parity check matrix with a sub matrix, the mother matrix can be extended. A method of extending the mother matrix will now be explained with reference to FIG. 8.

FIG. 8 is a block diagram illustrating an apparatus for generating a code according to an embodiment of the present invention. Referring to FIG. 8, the code generating apparatus includes a mother matrix generation unit 800 and a mother matrix extension unit 830. According to aspects of the present invention, the mother matrix generation unit 800 may be used alone, or may be used together with the mother matrix extension unit 830 to obtain a parity check matrix. That is, the mother matrix extension unit can be used selectively.

The mother matrix generation unit 800 includes an N-th information word matrix generation unit 810 and an N-th parity check matrix generation unit 820 (where N is a positive integer). The N-th information word matrix generation unit 810 generates an N-th information word matrix and provides the generated N-th information word matrix to the N-th parity check matrix generation unit 820. The N-th parity check matrix generation unit 820 generates an N-th parity check matrix by using the N-th information word matrix and a parity matrix or a parity check matrix previously generated.

That is, by using an input parity matrix and a first information word matrix, the N-th parity check matrix generation unit 820 generates and outputs a first parity check matrix. Then, by using a second information word matrix (provided by the N-th information word matrix generation unit 810) and the first parity check matrix, the N-th parity check matrix generation unit 820 generates a second parity check matrix.

The N-th parity check matrix generation unit 820 may generate a N-th parity check matrix so that the minimum distance or girth of the N-th parity check matrix is a maximum. Moreover, the minimum distance or girth of the generated first parity check matrix may be greater than or equal to the minimum distance or girth of the generated second check matrix.

The mother matrix extension unit 830 receives the mother matrix output from the mother matrix generation unit 800 and extends the mother matrix. That is, the mother matrix extension unit 830 extends the mother matrix by replacing each factor of the generated mother matrix with a sub matrix. The sub matrix may be generated so that the minimum distance or girth of the first parity check matrix in which each factor is replaced by the sub matrix can be a maximum. Likewise, the sub matrix may be generated so that the minimum distance or girth of the second parity check matrix in which each factor is replaced by the sub matrix can be a maximum. In addition, the minimum distance of the first parity check matrix in which each factor is replaced by the sub matrix may be greater than or equal to the minimum distance of the second parity check matrix in which each factor is replaced by the sub matrix.

When the mother matrix is thus extended, the sub matrix is generated so that the minimum distance or girth of the first parity check matrix can be a maximum. Accordingly, the mother matrix generation unit 800 does not necessarily design the first parity check matrix so that the minimum distance or girth of the first parity check matrix can be a maximum. Similarly, the mother matrix generation unit 800 does not necessarily design the first parity check matrix so that the minimum distance of the first parity check matrix is greater than or equal to the minimum distance of the second parity check matrix. Rather, the mother matrix extension unit 830 extends the mother matrix so that the minimum distance of the first parity check matrix is greater than or equal to the minimum distance of the second parity check matrix. That is, if the mother matrix extension unit 830 satisfies the condition of the minimum distance or girth, the mother matrix generation unit 800 does not have to satisfy the condition of the minimum distance or girth.

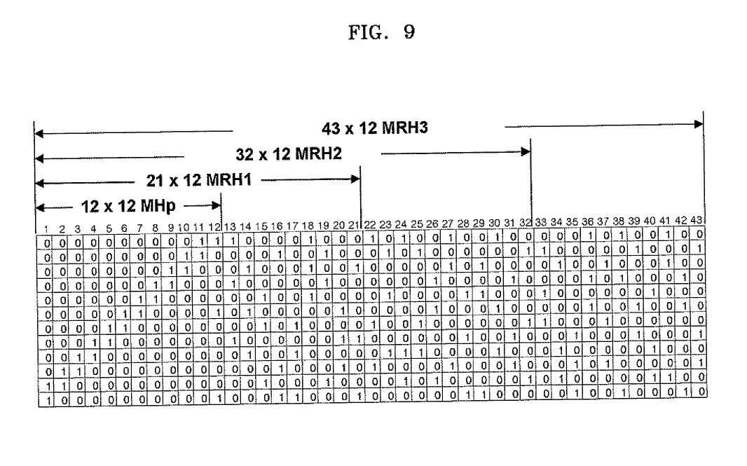

FIG. 9 is a diagram illustrating a parity matrix and an information word matrix according to an embodiment of the present invention. The matrix illustrated in FIG. 9 is a mother matrix in which each factor of the mother matrix has a corresponding sub matrix. A matrix formed by columns having weights equal to or less than a predetermined reference of Hi (i=1, 2, through n) is RHi and the mother matrix of RHi can be expressed as MRHi. FIG. 9 illustrates the mother matrix MRH3 for an H3 matrix. In a 12*12 MHP matrix for a parity part, 9 columns each having a weight of 3 are added for MRH1 (code rate 1/2), 11 columns each having a weight of 3 are added for MRH2 (code rate 2/3), and 11 columns each having a weight of 3 are added for MRH3 (code rate 3/4).

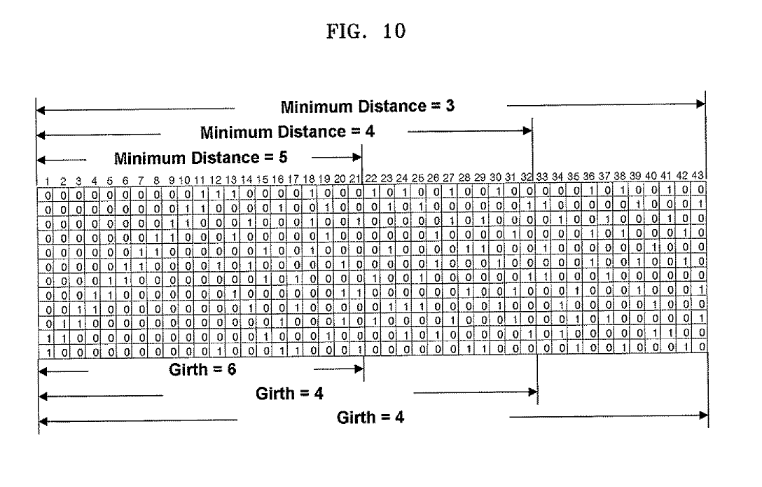

FIG. 10 is a diagram illustrating an LDPC code that is designed in relation to the parity matrix and information word matrix illustrated in FIG. 9 according to an embodiment of the present invention. FIG. 10 shows the minimum distances and girths of MRH1, MRH2, and MRH3 in the mother matrix MRH3 for an H3 matrix. As illustrated in FIG. 10, the minimum distances satisfy MRH1>MRH2>MRH3 and the girths satisfy MRH1>MRH2>MRH3.

To satisfy these minimum distance and girth conditions, one (or a set of columns formed by a predetermined number of columns) of columns 13 through 43 may be sequentially added to the columns 1 through 12 of MHp, and a column with a weight of 3 making the minimum distance or girth a maximum may be selected and added. In other words, when columns with a weight of 3 are added one by one, a 13th column that makes the minimum distance or girth of the first twelve columns MHp a maximum is added. Then, a 14th column that makes the minimum distance or girth a maximum is added to the formed 13 columns. In this manner, the LDPC code design is completed by adding columns to a 43rd column.

When a set of columns (formed by n columns), where each column has a weight of 3, is added, a first set of columns, where each column has a weight of 3, that makes the minimum distance or girth of the first twelve columns MHp a maximum are added. Then, a set of columns, where each column has a weight of 3, that makes the minimum distance or girth a maximum is added to the formed (12+n) columns. In this manner, MRH3 is completed by adding columns to a 43rd column.

It is understood that according to aspects of the present invention, the two methods described above (i.e., the method of adding columns one by one and the method of adding columns set by set) may be used concurrently.

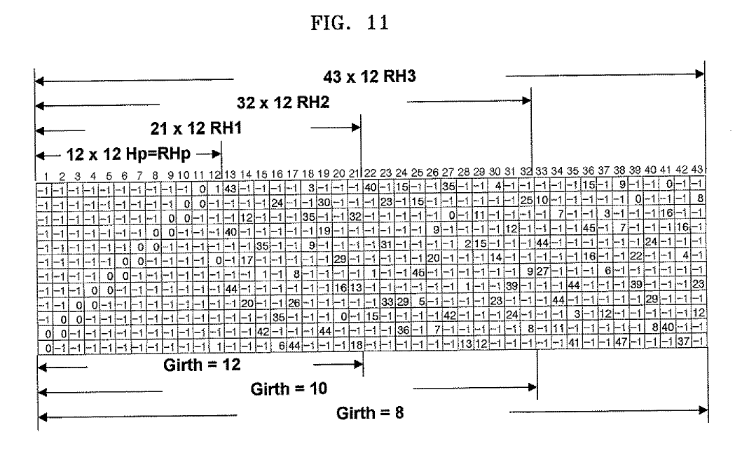

FIG. 11 is a diagram illustrating an LDPC code obtained by replacing a mother matrix illustrated in FIG. 10 with a sub matrix according to an embodiment of the present invention.

FIG. 11 illustrates RH1, RH2, and RH3 matrices and girths for each code rate formed by columns where each column has a weight less than or equal to a predetermined column weight in relation to columns excluding the parity matrix Hp of an H3 matrix.

RH3 is generated by replacing each factor of the mother matrix MRH3 illustrated in FIG. 10 by 48*48 sub matrices. The right-shift value of the sub matrices satisfies RH1>RH2>RH3 in terms of the respective girths. For this, Hp is first generated from MHp. Then, sequentially from the 13th column of the MRH3, a right-shift value of the 48*48 sub matrices is selected and designed so that the girth can be a maximum.

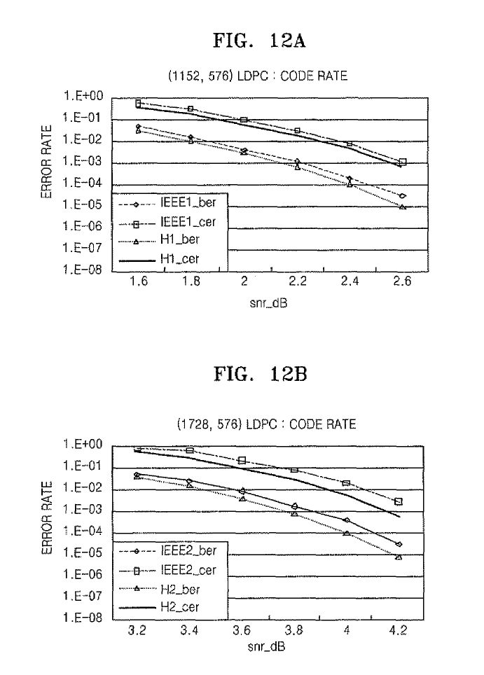

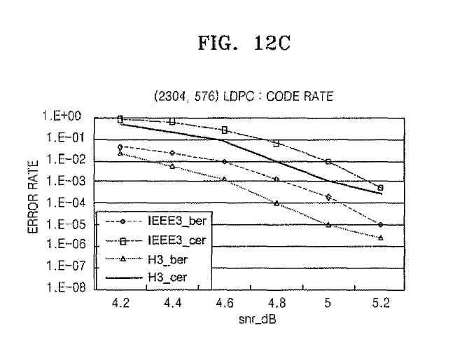

FIGS. 12A through 12C are graphs illustrating error rates of conventional LDPC codes and the LDPC codes according to an embodiment of the present invention. FIGS. 12A through 12C illustrate the bit error rates (BER) and the code word error rates (CER) of a 576*1152H matrix with a code rate 1/2, a 576*1728H matrix with a code rate 2/3, and a 576*2304H matrix with a code rate 3/4 according to conventional technology. Moreover, FIGS. 12A through 12C illustrate the BERs and CERs after error correction of a 576*1152H1 matrix, a 576*1728H2 matrix, and a 576*2304H3 matrix according to aspects of the present invention. As the results show, the error rates in the LDPC in the H1, H2, and H3 matrices according to aspects of the present invention are lower than the error rates of the conventional H matrices in each code rate. Therefore, it can be determined that the matrices according to aspects of the present invention have a better performance.

According to aspects of the present invention as described above, a method of designing an LDPC code having a variable code rate and enhancing the performance of error correction is provided. Moreover, according to aspects of the present invention, a plurality of code rates can be processed with one H matrix, thereby simplifying the complexity of LDPC design.

Aspects of the present invention can also be embodied as computer-readable codes on a computer-readable recording medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, optical data storage devices, and a computer data signal embodied in a carrier wave comprising a compression source code segment comprising the code and an encryption source code segment comprising the code (such as data transmission through the Internet). Aspects of the present invention may also be realized as a data signal embodied in a carrier wave and comprising a program readable by a computer and transmittable over the Internet.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of generating a low density parity check (LDPC) code having a variable code rate, the method comprising:
generating a first parity check matrix by combining a parity matrix or a parity check matrix and a first information word matrix; and
generating a second parity check matrix by combining the first parity check matrix and a second information word matrix.

2. The method as claimed in claim 1, wherein:
the generating of the first parity check matrix comprises generating the first parity check matrix so that a minimum_distance and/or a girth of_the first parity check matrix is a maximum, and
the generating of the second parity check matrix comprises generating the second parity check matrix so that a minimum distance and/or a girth of the second parity check matrix is a maximum.

3. The method as claimed in claim 1, wherein a minimum distance and/or a girth of the generated first parity check matrix is greater than or equal to a minimum distance and/or a girth of the generated second parity check matrix.

4. The method as claimed in claim 2, wherein the minimum distance and/or the girth of the generated first parity check matrix is greater than or equal to the minimum distance and/or the girth of the generated second parity check matrix.

5. The method as claimed in claim 1, further comprising:
generating a third parity check matrix by combining the second parity check matrix and a third information word matrix.

6. The method as claimed in claim 1, wherein a code rate of the first parity check matrix is less than a code rate of the second parity check matrix.

7. The method as claimed in claim 1, wherein:
the first information word matrix and the second information word matrix are formed by a plurality of columns; and
each column has a weight less than or equal to a predetermined weight.

8. The method as claimed in claim 1, further comprising:
replacing each of factors of the second parity check matrix with a sub matrix.

9. The method as claimed in claim 8, wherein the replacing of each factor of the second parity check matrix with the sub matrix comprises:
generating the sub matrices so that a minimum distance and/or a girth of the first parity check matrix is a maximum, and a minimum distance and/or a girth of the second parity check matrix is a maximum.

10. The method as claimed in claim 9, wherein the minimum distance and/or the girth of the first parity check matrix in which each factor is replaced by the sub matrix is greater than or equal to the minimum distance and/or the girth of the second parity check matrix in which each factor is replaced by the sub matrix.

11. The method as claimed in claim 8, wherein the replacing of each factor of the second parity check matrix with the sub matrix comprises:
replacing each factor of the second parity check matrix with a sub matrix such that a minimum distance and/or a girth of the first parity check matrix is greater than or equal to a minimum distance and/or a girth of the second parity check matrix.

12. A computer readable recording medium encoded with the method of claim 1 and implemented by a computer.

13. An apparatus for generating an LDPC code word having a variable code rate, the apparatus comprising:
an information word generation unit to generate an N-th information word matrix, where N is an integer greater than or equal to 1; and
a parity check matrix generation unit to generate an N-th parity check matrix by combining the generated N-th information word matrix and a parity matrix or an (N-1)-th parity check matrix.

14. The apparatus as claimed in claim 13, wherein the parity check matrix generation unit generates a first parity check matrix by combining the parity matrix and a first information word matrix, and generates a second parity check matrix by combining the first parity check matrix and a second information word matrix.

15. The apparatus as claimed in claim 14, wherein the parity check matrix generation unit generates the first parity check matrix so that a minimum distance and/or a girth of the first parity check matrix is a maximum, and generates the second parity check matrix so that a minimum distance and/or a girth of the second parity check matrix is a maximum.

16. The apparatus of claim 14, wherein a minimum distance and/or a girth of the generated first parity check matrix is greater than or equal to a minimum distance and/or a girth of the generated second parity check matrix.

17. The apparatus of claim 15, wherein the minimum distance and/or the girth of the generated first parity check matrix is greater than or equal to the minimum distance and/or the girth of the generated second parity check matrix.

18. The apparatus as claimed in claim 14, wherein a code rate of the first parity check matrix is lower than a code rate of the second parity check matrix.

19. The apparatus as claimed in claim 13, wherein a code rate of the (N-1)th parity check matrix is lower than a code rate of the Nth parity check matrix.

20. The apparatus as claimed in claim 14, wherein:
the first information word matrix and the second information word matrix are formed by a plurality of columns; and
each column has a weight less than or equal to a predetermined weight.

21. The apparatus as claimed in claim 14, further comprising:
a mother matrix extension unit to replace each of factors of the second parity check matrix with a sub matrix.

22. The apparatus as claimed in claim 13, further comprising:
a mother matrix extension unit to replace each of factors of the Nth parity check matrix with a sub matrix.

23. The apparatus as claimed in claim 22, wherein the mother matrix extension unit generates the sub matrices so that a minimum distance and/or a girth of the (N-1)th parity check matrix is a maximum, and generates the sub matrices so that a minimum distance and/or a girth of the Nth parity check matrix is a maximum.

24. The apparatus as claimed in claim 23, wherein the minimum distance and/or the girth of the (N-1)th parity check matrix in which each factor is replaced by the sub matrix is greater than or equal to the minimum distance and/or the girth of the Nth parity check matrix in which each factor is replaced by the sub matrix.

25. A method of generating an LDPC code word having a variable code rate, the method comprising:
generating an N-th information word matrix, where N is an integer greater than or equal to 1; and
generating an N-th parity check matrix by combining the generated N-th information word matrix and a parity matrix or an (N-1)-th parity check matrix.

26. The method as claimed in claim 25, wherein:
the generating of the N-th parity check matrix comprises generating the N-th parity check matrix so that a minimum distance and/or a girth of the N-th parity check matrix is a maximum.

27. The method as claimed in claim 25, wherein a minimum distance and/or a girth of the generated N-th parity check matrix is greater than or equal to a minimum distance and/or a girth of the (N-1)-th parity check matrix.

28. The method as claimed in claim 25, wherein a code rate of the (N-1)-th parity check matrix is less than a code rate of the N-th parity check matrix.

29. A method of extending an LDPC code having a variable code rate and including a parity check matrix, the method comprising:
replacing each of factors of the parity check matrix with a sub matrix, wherein
a minimum distance and/or a girth of the parity check matrix in which each factor is replaced is a maximum.

30. The method as claimed in claim 29, wherein the parity check matrix is an N-th parity check matrix generated by combining an N-th information word matrix, where N is a positive integer, with a parity matrix or an (N-1)-th parity check matrix.

31. The method as claimed in claim 30, wherein a code rate of the (N-1)-th parity check matrix is less than a code rate of the N-th parity check matrix.

32. The method as claimed in claim 30, wherein the minimum distance and/or the girth of the parity check matrix is less than or equal to a minimum distance and/or a girth of the (N-1)-th parity check matrix.

33. An apparatus for extending an LDPC code having a variable code rate and including a parity check matrix, the apparatus comprising:
a matrix extension unit to replace each of factors of the parity check matrix with a sub matrix, wherein
a minimum distance and/or a girth of the parity check matrix in which each factor is replaced is a maximum.

34. The method as claimed in claim 33, wherein the parity check matrix is an N-th parity check matrix generated by combining an N-th information word matrix, where N is a positive integer, with a parity matrix or an (N-1)-th parity check matrix.

35. The method as claimed in claim 34, wherein a code rate of the (N-1)-th parity check matrix is less than a code rate of the N-th parity check matrix.

36. The method as claimed in claim 34, wherein the minimum distance and/or the girth of the parity check matrix is less than or equal to a minimum distance and/or a girth of the (N-1)-th parity check matrix.
